(19) United States
(12) Patent Application Publication
(10) Pub. No.: US 2026/0293705 A1
(43) Pub. Date: Sep. 24, 2026

(54) OBSERVABLE SOLDER CONTACTS IN STACKED COMPONENTS

(71) Applicant: Allegro MicroSystems, LLC, Manchester, NH (US)

(72) Inventors: Vijay Mangtani, Nashua, NH (US); Paul A. David, Bow, NH (US)

(73) Assignee: Allegro MicroSystems, LLC, Manchester, NH (US)

(21) Appl. No.: 19/083,970

(22) Filed: Mar. 19, 2025

(51) Int. Cl. H10W 70/40; H10W 70/04; H10W 90/00

(52) U.S. Cl. CPC H10W 70/429; H10W 70/048; H10W 90/00; H10W 90/811; H10W 90/722

(57) ABSTRACT

According to one aspect of the present disclosure, a voltage isolated integrated circuit (IC) assembly includes a first component comprising a first width and a first length to form a first recess to allow for inspection of a lead set of a second component. In some embodiments, the lead set extends out of the second component at a second length to form an electrical and mechanical connection to a substrate. In some embodiments, the first component is stacked on top of the second component such that the first and second components are in a stacked configuration.

### BACKGROUND

Voltage isolation can be used for electronic components having circuit components with two separate voltage levels connected to the electrical connections of the component. Magnetic coupling typically relies on use of a transformer to couple, yet galvanically separate, circuits on the different sides of the transformer, typically referred to as the primary and secondary sides. Galvanic isolation typically includes electrical isolation coupled with lack of direct electrical contact between the circuit components. Such galvanic isolation can be used to separate circuits in order to protect users from coming into direct contact with hazardous voltages. Galvanic isolation may also be used to simplify circuit design, reduce cost, or improve system performance.

Integrated circuit (IC) packaging techniques can be used for isolated voltage circuits like ones utilizing magnetic coupling. The packaging techniques may be used to integrate one or more semiconductor dies into a module, package, or component, for example by encapsulating the die with a non-conductive, insulating mold material. The term “clearance” refers to the shortest distance through air between two conductive parts, such as the primary and secondary leads. The term “creepage” refers to the shortest distance between two conductive parts along the surface of any insulation material common to both parts. The spacing distance between components that are required to withstand a given working voltage (i.e., the highest voltage level that insulation under consideration can be subjected to when a device is operating under normal use) is specified in terms of creepage and clearance. Meeting specified creepage and clearance requirements can become challenging, particularly as component dimensions are reduced.

### SUMMARY OF DISCLOSED EMBODIMENTS

According to one aspect of this disclosure, a voltage isolated integrated circuit (IC) assembly comprises a first component comprising a first width and a first length to form a first recess to allow for inspection of a lead set of a second component. In some embodiments, the lead set extends out of the second component at a second length to form an electrical and mechanical connection to a substrate. In some embodiments, the first component is stacked on top of the second component such that the first and second components are in a stacked configuration.

In some embodiments, the first component has the first recess on one side of the first component and a second recess on an opposing side of the first component such that the first component forms an H shape. In some embodiments, the first length, the first width, and a second length of the first component that form the first recess extend to form a C shape. In some embodiments, a portion of the first length and the first width of the first component that form the first recess extend at a substantially radiused angle. In some embodiments, a portion of the first length and the first width of the first component that form the first recess extend at a substantially right angle. In some embodiments, the first component has a third width and a third length to form a third recess. In some embodiments, the first component has a third width and a third length to form a third recess and the third width is less than the first width. In some embodiments, the first component has a third width and a third length to form a third recess and the third recess is adjacent to the first recess. In some embodiments, the first component has a third width and a third length to form a third recess and the third length is smaller than the first length. In some embodiments, the IC assembly further comprises two or more leads from the lead set that extend towards the first component to form a direct electrical connection to two or more leads of the first component.

According to another aspect of the present disclosure, a method comprises a first component comprising a first length and a first width forming a first recess to allow for inspection of a lead set from a second component. In some embodiments, the lead set extends out of the second component at a second length to form an electrical and mechanical connection to a substrate. In some embodiments, the first component is stacked on top of the second component such that the first and second components are in a stacked configuration.

In some embodiments, the first component has the first recess on one side of the first component and a second recess on an opposing side of the first component such that the first component forms an H shape. In some embodiments, the first length, the first width, and a second length of the first component that form the first recess extend to form a C shape. In some embodiments, the first component has a third width and a third length to form a third recess. In some embodiments, the first component has a third width and a third length to form a third recess and the third width is less than the first width. In some embodiments, the first component has a third width and a third length to form a third recess and the third recess is adjacent to the first recess. In some embodiments, the first component has a third width and a third length to form a third recess and the third length is smaller than the first length. In some embodiments, the method further comprises providing two or more leads from the lead set that extend towards the first component to form a direct electrical connection to two or more leads of the first component.

According to another aspect of the present disclosure, a voltage isolated integrated circuit (IC) assembly comprises a second component disposed on a substrate comprising a lead set that extends out of the second component at a second length and connects to the substrate; and a first component disposed on the second component comprising a first width and a first length to form a first recess to allow for inspection of the lead set. In some embodiments, the first component is stacked on top of the second component such that the first and second components are in a stacked configuration.

In some embodiments, the first component has the first recess on one side of the first component and a second recess on an opposing side of the first component such that the first component forms an H shape. In some embodiments, the first length, the first width, and a second length of the first component that form the first recess extend to form a C shape. In some embodiments, the first component has a third width and a third length to form a third recess. In some embodiments, the first component has a third width and a third length to form a third recess and the third width is greater than the first width. In some embodiments, the first component has a third width and a third length to form a third recess and the third recess is adjacent to the first recess. In some embodiments, the first component has a third width and a third length to form a third recess and the third length is smaller than the first length. In some embodiments, the first component and the second component are mechanically coupled together. In some embodiments, the first component and the second component are mechanically coupled together and the IC assembly further comprises a non-conductive adhesive disposed between the first component and the second component. In some embodiments, the IC assembly further comprises two or more leads from the lead set that extend towards the first component to form a direct electrical connection to two or more leads of the first component.

According to another aspect of the present disclosure, a voltage isolated integrated circuit (IC) assembly comprises a second component disposed on a substrate comprising a lead set that extends out of the second component at a second length and connects to the substrate; and a first component disposed on the second component comprising a first length and a first width to allow for inspection of the lead set.

In some embodiments, the second component has a second length and a third width, wherein the second length is larger than the first length and the first width is larger than the third width. In some embodiments, the first component and the second component are mechanically coupled together. In some embodiments, the first component and the second component are mechanically coupled together and the IC assembly further comprises a non-conductive adhesive disposed between the first component and the second component.

In some embodiments, the IC assembly further comprises two or more leads from the first lead set that extend towards a bottom surface of the first component. In some embodiments, the IC assembly further comprises two or more leads from the first lead set that extend towards a bottom surface of the first component and the two or more leads are bent to form a J-bend. In some embodiments, the IC assembly further comprises two or more leads from the first lead set that extend towards a bottom surface of the first component and the two or more leads are curled. In some embodiments, the IC assembly further comprises two or more leads from the first lead set that extend towards a bottom surface of the first component and the two or more leads are shaped. In some embodiments, the IC assembly further comprises an electrically conductive material positioned on the two or more of the leads. In some embodiments, the IC assembly further comprises an electrically conductive material positioned on the two or more of the leads and the electrically conductive material is conductive epoxy or solder, non-conductive epoxy, or silicone.

### DESCRIPTION OF THE SEVERAL VIEWS OF THE DRAWINGS

The manner and process of making and using the disclosed embodiments may be appreciated by reference to the figures of the accompanying drawings. It should be appreciated that the components and structures illustrated in the figures are not necessarily to scale, emphasis instead being placed upon illustrating the principals of the concepts described herein. Like reference numerals designate corresponding parts throughout the different views. Furthermore, embodiments are illustrated by way of example and not limitation in the figures, in which:

FIG. 1A is a top view of a voltage isolated integrated circuit (IC) assembly with a first component with a first recess on one side and a second recess on an opposing side, in accordance with the present disclosure;

FIG. 1B is a cross-sectional view of the IC assembly of FIG. 1A;

FIG. 1C is a side view of the IC assembly of FIG. 1A;

FIG. 1D is a perspective view of the IC assembly of FIG. 1A;

FIG. 2 is a top view of an IC assembly with a first component with a first shallow recess and a radiused portion, in accordance with the present disclosure;

FIG. 3 is a top view of an IC assembly with a first component including a first recess on one side, a second recess on an opposing side, and a third shallow recess adjacent to the first recess, in accordance with the present disclosure;

FIG. 4 is a top view of an IC assembly with a first component with a first recess on one side, a second recess on an opposing side, and a third recess on the same side as the first recess, in accordance with the present disclosure;

FIG. 5A is a top view of an IC assembly with a first component disposed on a second component comprising a first width and a first length to allow for inspection of a lead set, in accordance with the present disclosure;

FIG. 5B is a cross sectional view of the IC assembly of FIG. 5A;

FIG. 5C is a perspective view of the IC assembly of FIG. 5A; and

FIG. 5D is a side view of various illustrations of formed lead configurations.

### DETAILED DESCRIPTION

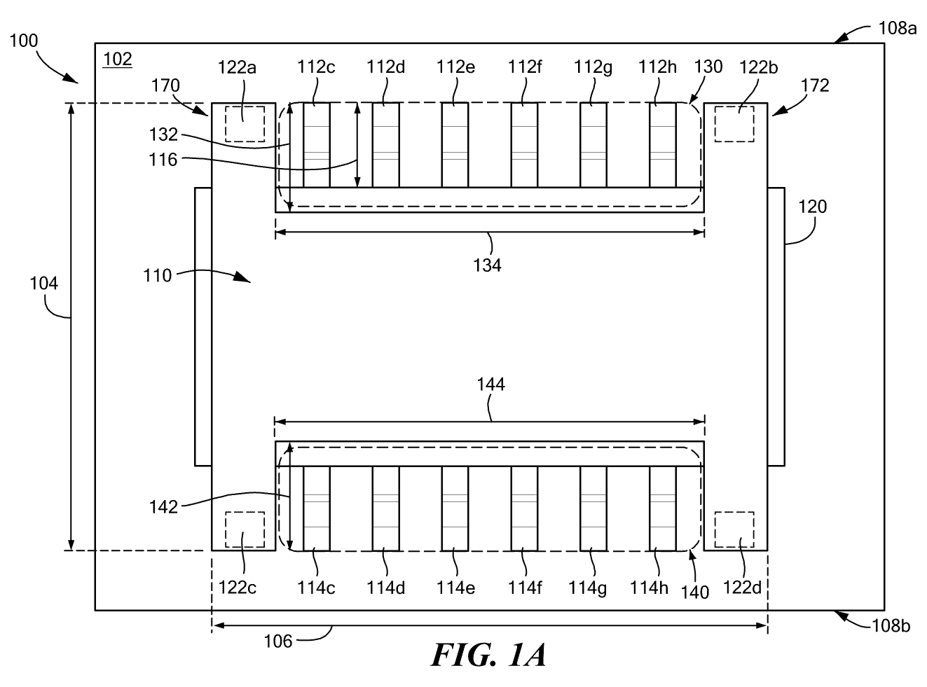

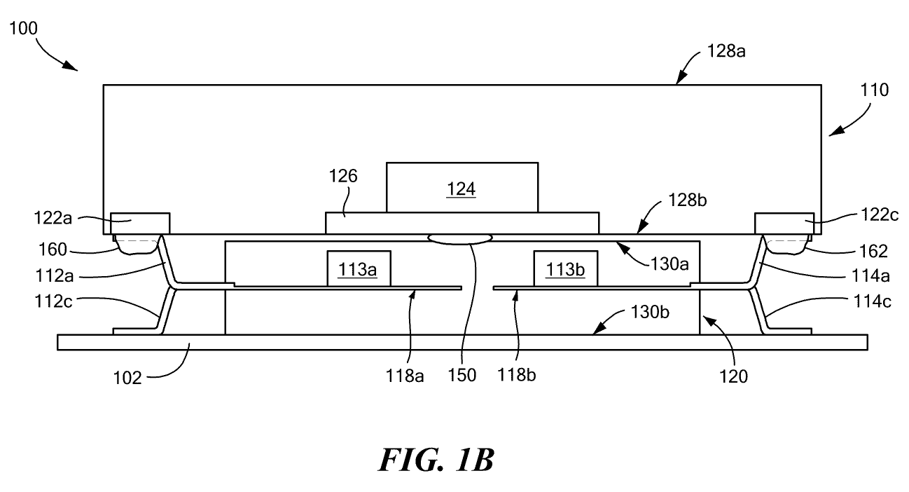

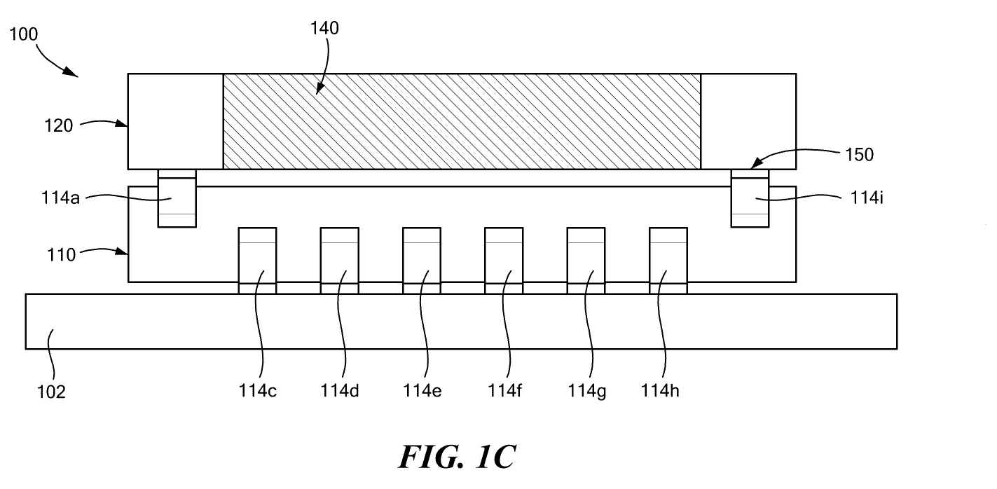

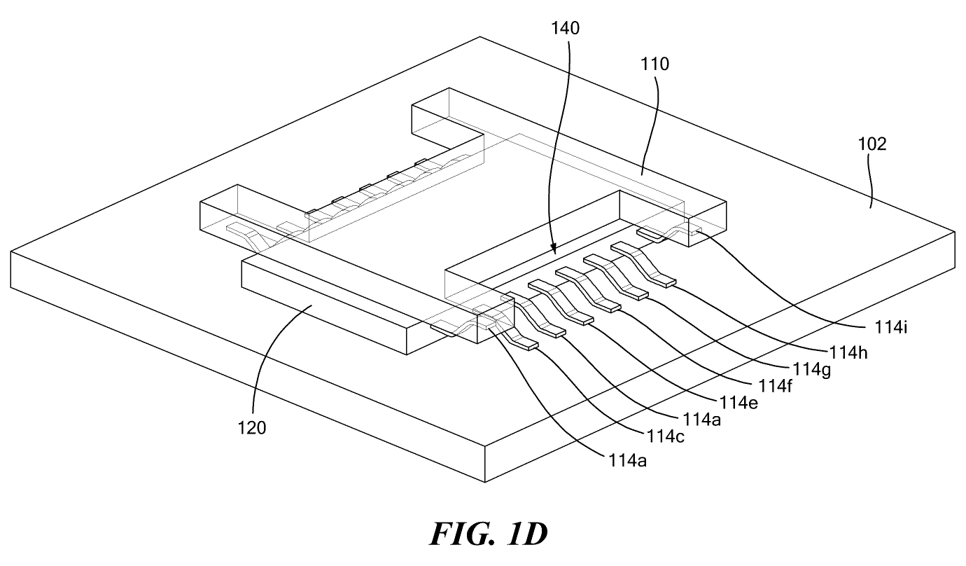

Referring to FIGS. 1A, 1B, 1C, and 1D, a voltage isolated integrated circuit (IC) assembly 100 includes a first component 110 stacked on top of a second component 120, such that the first component 110 and the second component 120 are in a stacked configuration. The second component 120 includes a lead set 112a (FIG. 1B), 112c, 112d, 112e, 112f, 112g, 112h (FIG. 1A), 114a (FIG. 1B), 114c, 114d, 114e, 114f, 114g, 114h (FIG. 1A), 114i (FIG. 1C) to permit electrical connection to components within the second component 120. A first recess 130 in the first component 110 has a first width 132 and a first length 134 to allow for inspection of a subset of a lead set 112c, 112d, 112e, 112f, 112g, 112h (FIG. 1A) of the second component 120. The IC assembly 100 can be mounted on a printed circuit board (PCB), lang grid array (LGA), a ceramic, glass, or other suitable substrate 102 for use in an application system.

The first component 110 has a second width 104 and a second length 106, with a first portion 170 and a second portion 172 extending along a portion of the second width 104. The first length 134, the first width 132, and the second length 106 of the first component 110 that form the first recess 130 extend to form a C shape. The first portion 170 and the second portion 172 form sides of the C shape. The first component 110 has a third width 142 and a third length 144 to form a second recess 140 to allow for inspection of a subset of a lead set 114c, 114d, 114e, 114f, 114g, 114h (FIG. 1A) of the second component 120. The first component 110 includes the first recess 130 on one side 108a and the second recess 140 on an opposing side 108b, such that the first component 110 forms an H shape.

The inspectable leads of the second component 120 include a lead set 112c, 112d, 112e, 112f, 112g, 112h (FIG. 1A), 114c, 114d, 114e, 114f, 114g, 114h (FIG. 1A) that permit electrical connection to components within the second component 120. A subset of the lead set 112c, 112d, 112e, 112f, 112g, 112h (FIG. 1A) extends out of the second component 120 at a second length 116. The subset of the lead set 112c, 112d, 112e, 112f, 112g, 112h (FIG. 1A) extends out at the second length 116, such that the subset of the lead set 112c, 112d, 112e, 112f, 112g, 112h (FIG. 1A) is visible through the first recess 130 enabling inspection. A subset of the lead set 114c, 114d, 114e, 114f, 114g, 114h (FIG. 1A) extends out of the second component at a length to form an electrical and mechanical connection to the substrate 102. A subset of the lead set 112a, 114a (FIG. 1B), 114i (FIG. 1C) are not visible through a recess and thus are not inspectable.

The second component 120 includes a lead frame 118a, 118b (FIG. 1B) that supports two or more semiconductor dies 113a, 113b, with a first die 113a disposed on a first lead frame portion 118a and a second die 113b disposed on a second lead frame portion 118b. The lead frame 118a, 118b (FIG. 1B) may be a single layer material such as copper or may be a multiple layer substrate in the form of a molded interconnect substrate (MIS). The MIS may include multiple layers of copper with insulation between the layers of copper. The lead frame 118a, 118b (FIG. 1B) provides the lead set, including leads 112a (FIG. 1B), 112c, 112d, 112e, 112f, 112g, 112h (FIG. 1A), 114a (FIG. 1B), 114c, 114d, 114e, 114f, 114g, 114h (FIG. 1A), 114i (FIG. 1C).

The first die 113a and the second die 113b can be coupled to lead frame 118a, 118b by various mounting methodologies including, but not limited to the use of wire bonds to plated areas on the lead frame in a so-called die up orientation or conductive bumps or pillars to plated areas of the lead frame in a so-called flip-chip orientation. Lead-on-chip assemblies are also possible. The dies 113a, 113b can support various processing circuitry to process signals sought to be isolated by a transformer 124. Additional circuitry beyond that supported by dies 113a, 113b can be included in the first component 110 in the form of one or more discrete components, such as a capacitor.

The first component 110 contains the transformer 124. The first component 110 includes a lead frame 126 to support the transformer 124 and provide the lead set 122a, 122b, 122c, 122d (FIG. 1A). The lead set 122a, 122b, 122c, 122d (FIG. 1A) permits electrical connection to the transformer 124. Alternatively, the first component 110 can include other types of structures to support the transformer and provide leads 122a, 122b, 122c, 122d (FIG. 1A). Example leads of the leads 122a, 122b, 122c, 122d (FIG. 1A) can be of a QFN (Quad-Flat No-leads), or DFN (Dual-Flat No-Leads) type, such that the leads include conductive pads exposed from side and bottom surfaces of the first component 110.

In embodiments, a subset of the lead set including leads 112a, 114a (FIG. 1B), 114i (FIG. 1C) of the second component 120 are configured for direct electrical connection with leads 122a, 122c, 122d (FIG. 1A) of the first component 110. The second component 120 includes two or more leads 112a, 114a (FIG. 1B), 114i (FIG. 1C) from the lead set that extend towards the first component 110 to form a direct electrical connection to one or more leads 122a, 122c, 122d (FIG. 1A) of the first component 110. By “direct electrical connection” it is meant that direct physical contact provides an electrical connection between the leads 112a, 114a (FIG. 1B), 114i (FIG. 1C) of the second component 120 and the leads 122a, 122c, 122d (FIG. 1A) of the first component 110, respectively, as shown. Another subset of the leads from the lead set 112c, 112d, 112e, 112f, 112g, 112h (FIG. 1A), 114c, 114d, 114e, 114f, 114g, 114h (FIG. 1A) of the second component 120 are configured for direct electrical connection to the substrate 102.

It will be appreciated by those of ordinary skill in the art that although the various leads 112a (FIG. 1B), 112c, 112d, 112e, 112f, 112g, 112h (FIG. 1A), 114a (FIG. 1B), 114c, 114d, 114e, 114f, 114g, 114h (FIG. 1A), 114i (FIG. 1C), 122a, 122b, 122c, 122d (FIG. 1A) are shown with varying numbers of leads, respectively, other numbers of leads are possible including more or fewer leads. Further, although the various leads 112a (FIG. 1B), 112c, 112d, 112e, 112f, 112g, 112h (FIG. 1A), 114a (FIG. 1B), 114c, 114d, 114e, 114f, 114g, 114h (FIG. 1A), 114i (FIG. 1C) extend from the component 120 only from opposite parallel component sides, in some embodiments, one or more leads of one or both lead sets can extend from a component side that is orthogonal with respect to the illustrated sides from which they extend.

In embodiments, the first component 110 includes a mold material that encloses the transformer to form a body of the first component 110. The mold material may be a compliant material. A compliant material is one that is soft or less rigid, so it is able to absorb vibration, for example as may result from the operation of the transformer. The mold material can be provided with various process techniques, such as transfer molding, potting, or injection molding. Various materials can be used for the mold material, including, but not limited to silicone, epoxy, or a plastic material. In embodiments, a mold material is used to form the body of the first component 110. A mold material can used to form a body of the second component 120.

In embodiments, the first component 110 and the second component 120 are mechanically coupled together. The first component 110 has a top surface 128a and a bottom surface 128b. The second component 120 has a top surface 130a and a bottom surface 130b. The bottom surface 128b of the first component 110 contacts the top surface 130a of the second component 120.

In embodiments, a non-conductive adhesive 150 is disposed between first component 110 and the second component 120. The non-conductive adhesive 150 is disposed between the bottom surface 128b of the first component 110 and the top surface 130a of the second component 120 to further enhance mechanical coupling of the components. The non-conductive adhesive 150 may be a polymer or an epoxy. The non-conductive adhesive 150 may be printed, dispensed, or otherwise applied.

Referring to FIG. 1B, the IC assembly 100 is includes an additional feature in the form of electrically conductive material 160, 162. A first electrically conductive material 160 is disposed on a lead 122a of the first component 110 and a lead 112a of the second component 120. A second electrically conductive material 162 is disposed on lead 122c of the first component 110 and lead 114a of the second component 120. The electrically conductive material 160, 162 can enhance the electrical connection between the leads 122a, 122c (FIG. 1B) of the first component 110 and leads 112a, 114a (FIG. 1B) of the second component 120. Suitable materials for the electrically conductive material 160, 162 include, but are not limited to conductive epoxy or solder, such as eutectic tin lead, a low stress non-conductive epoxy, or silicone. The electrically conductive material 160, 162 may be disposed through a jetting system or a needle.

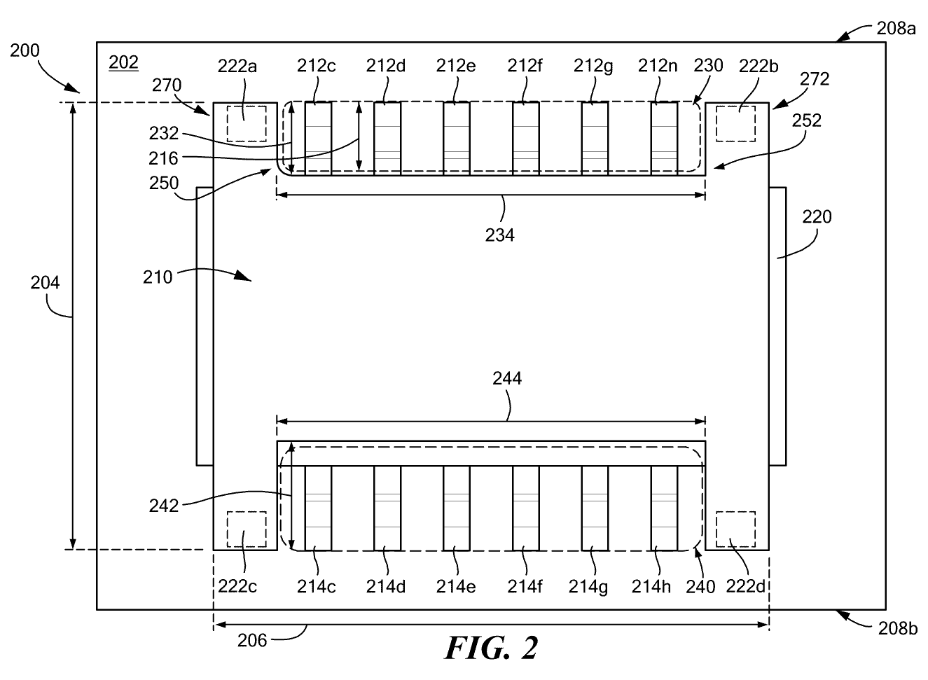

FIG. 2 is a top view of an IC assembly 200 including a first component 210 stacked on top of a second component 220, such that the first component 210 and the second component 220 are in a stacked configuration. The IC assembly 200 can be mounted on a substrate 202, which may be similar to or the same as substrate 102. The second component 220 can be similar to the second component 120 and thus, can include a lead set 212c, 212d, 212e, 212f, 212g, 212h, 214c, 214d, 214e, 214f, 214g, 214h to permit electrical connection to components within the second component 220. The lead set 212c, 212d, 212e, 212f, 212g, 212h, 214c, 214d, 214e, 214f, 214g, 214h is configured for electrical connection to the substrate 202. A recess in the first component 210 has a first width 232 and a first length 234 to allow for inspection of a subset of a lead set 212c, 212d, 212e, 212f, 212g, 212h of the second component 220. The subset of the lead set 212c, 212d, 212e, 212f, 212g, 212h extends out of the second component 220 at a length 216, such that the lead set 212c, 212d, 212e, 212f, 212g, 212h is visible through the first recess 230 enabling inspection.

The first component 210 can be similar to the first component 110 and thus, can include a lead set 222a, 222b, 222c, 222d to permit electrical connection to components within the first component 210. The first component 210 has a second width 204 and a second length 206, with a first portion 270 and a second portion 272 extending along a portion of the second width 204. The first component 210 has a third width 242 and a third length 244 to form a second recess 240 to allow for inspection of a subset of the lead set 214c, 214d, 214e, 214f, 214g, 214h of the second component 220. The first component 210 includes the first recess 230 on one side 208a and the second recess 240 on an opposing side 208b. The first recess 230 is substantially shallow, in comparison to the second recess 240, meaning the first width 232 is less than the third width 242.

In embodiments, a portion 250 of the first length 234 and the first width 232 of the first component 210 that form the first recess 230 extend at a substantially radiused angle 250. In embodiments, a portion 252 of the first length 234 and the first width 232 of the first component 210 that form the first recess 230 extend at a substantially right angle 252. In embodiments, there may be a substantially reduced angle 250 and a substantially right angle 252 in the same recess 230. In embodiments, there may be only substantially reduced angles or substantially right angles in the recess.

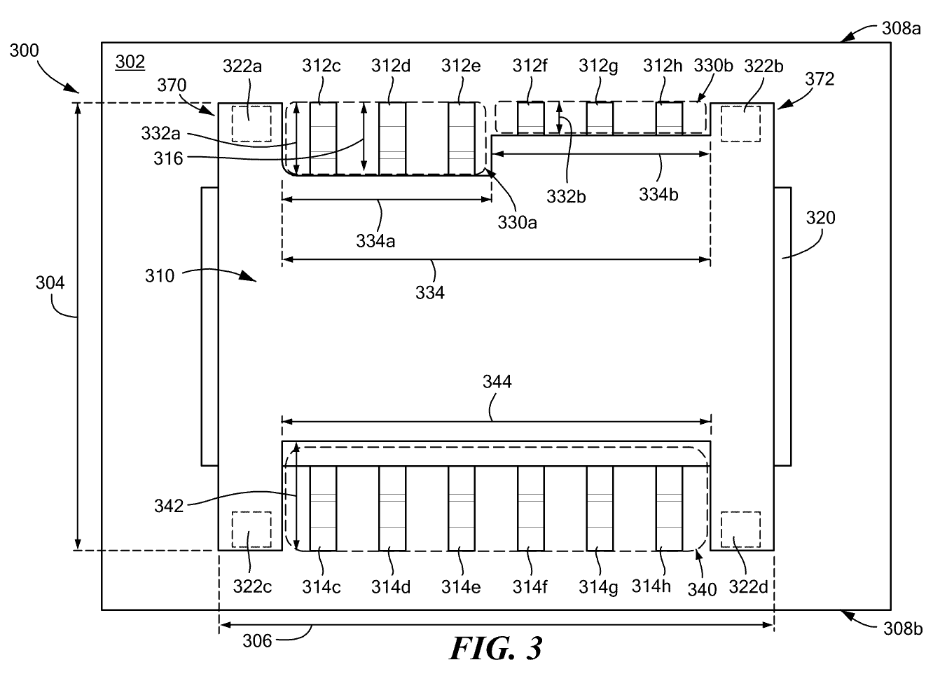

FIG. 3 is a top view of an IC assembly 300 including a first component 310 stacked on top of a second component 320, such that the first component 310 and the second component 320 are in a stacked configuration. The IC assembly 300 can be mounted on a substrate 302, which may be similar to or the same as substrate 102. The second component 320 can be similar to the second component 120 and thus, can include a lead set 312c, 312d, 312e, 312f,312g, 312h, 314c, 314d, 314e, 314f, 314g, 314h to permit electrical connection to components within the second component 320. The lead set 312c, 312d, 312e, 312f, 312g, 312h, 314c, 314d, 314e, 314f, 314g, 314h is configured for electrical connection to the substrate 302. A recess 330 in the first component 310 has a first width 332 and a first length 334 to allow for inspection of a subset of a lead set 312c, 312d, 312e of the second component 320. A subset of the lead set 312c, 312d, 312e, 312f, 312g, 312h extends out of the second component 320 at a length 316, such that the lead set 314c, 314d, 314e, 314f, 314g, 314h is visible through the recesses 330a, 330b enabling inspection.

The first component 310 can be similar to the first component 110 and thus, can include a lead set 322a, 322b, 322c, 322d to permit electrical connection to components within the first component 310. The first component 310 has a second width 304 and a second length 306, with a first portion 370 and a second portion 372 extending along a portion of the second width 304.

The first component 310 has a third width 342 and a third length 344 to form a second recess 340 to allow for inspection of a subset of the lead set 314c, 314d, 314e, 314f, 314g, 314h of the second component 320. The first component 310 includes the recesses 330a, 330b on one side 308a extending along a length 334 and the second recess 340 on an opposing side 308b. The first component 310 has a third width 332b and a third length 334b to form a third recess 330b to allow for inspection of a subset of the lead set 312f, 312g, 312h. The third recess 330b is adjacent to the first recess 330a. The third width 332b is less than the first width 332a. In embodiments, the third width 332b may be substantially less than the first width 332a.

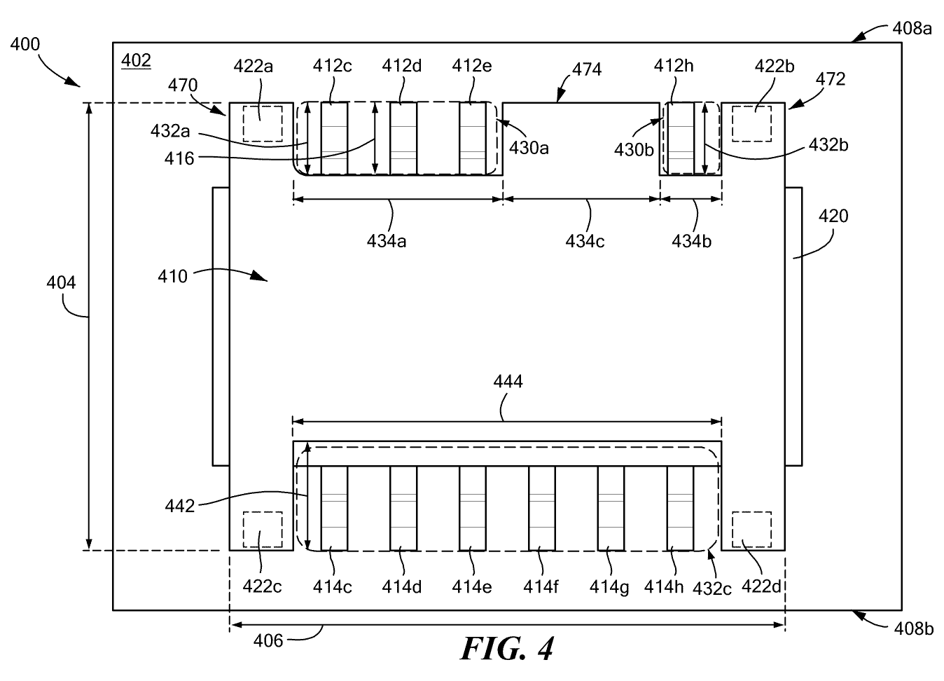

FIG. 4 is a top view of an IC assembly 400 including a first component 410 stacked on top of a second component 420, such that the first component 410 and the second component 420 are in a stacked configuration. The IC assembly 400 can be mounted on a substrate 402, which may be similar to or the same as substrate 102. The second component 420 can be similar to the second component 120 and thus, can include a lead set 412c, 412d, 412e, 412h, 414c, 414d, 414e, 414f, 414g, 414h to permit electrical connection to components within the second component 420. A subset of the lead set 412c, 412d, 412e, 412h, 414c, 414d, 414e, 414f, 414g, 414h is configured for electrical connection to the substrate 402. A recess 430a formed in the first component 410 has a first width 432 and a first length 434 to allow for inspection of a subset of a subset of a lead set 412c, 412d, 412e of the second component 420. The lead set 412c, 412d, 412e, 412h extends out of the second component 420 at a length 416, such that the lead set 412c, 412d, 412e, 412h is visible through the recesses 430a, 430c enabling inspection.

The first component 410 can be similar to the first component 410 and thus, can include a lead set 422a, 422b, 422c, 422d to permit electrical connection to components within the first component 410. The first component 410 has a second width 404 and a second length 406, with a first portion 470 and a second portion 472 extending along a portion of the second width 404.

The first component 410 has a third width 432b and a third length 434b to form a second recess 430b to allow for inspection of a subset of the lead set 412h of the second component 420. A third portion 474 extending along the second width 404 and a fourth length 434c disposed between the first recess 430a and the second recess 430b. The width of the third portion 474 may be adjusted to enable inspection of a subset of the leads. The third length 434b is smaller than the first length 434a. The fourth length 434c, and accordingly the third length 434b and/or the first length 434a, may be adjusted to allow for inspection of some or all of the leads. For example, as disclosed in FIG. 4, the lead 412f is visible for inspection through second recess 430b. The first component 410 has a third width 442 and a third length 444 to form a third recess 432c to allow for inspection of a lead set 414c, 414d, 414e, 414f, 414g, 414h of the second component 420.

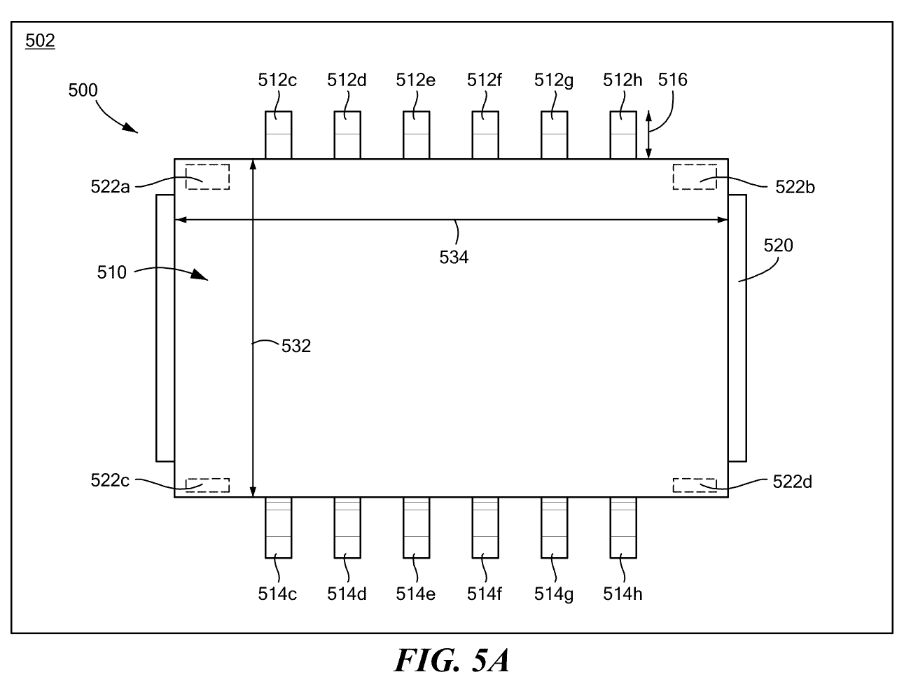

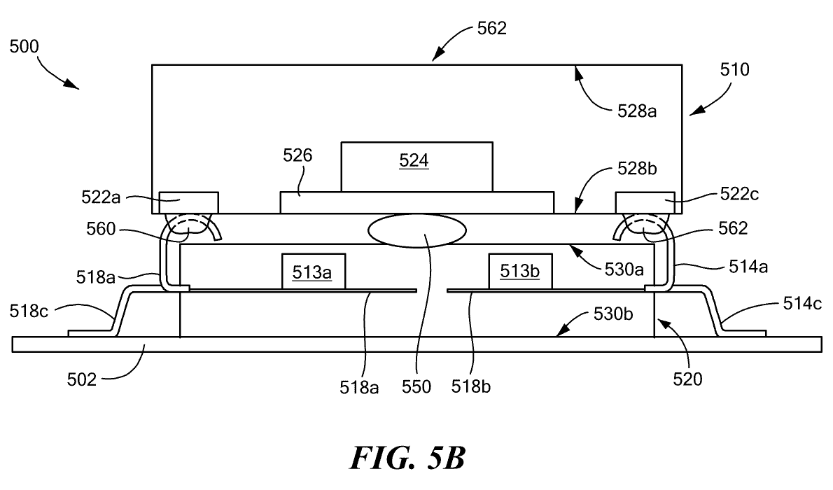

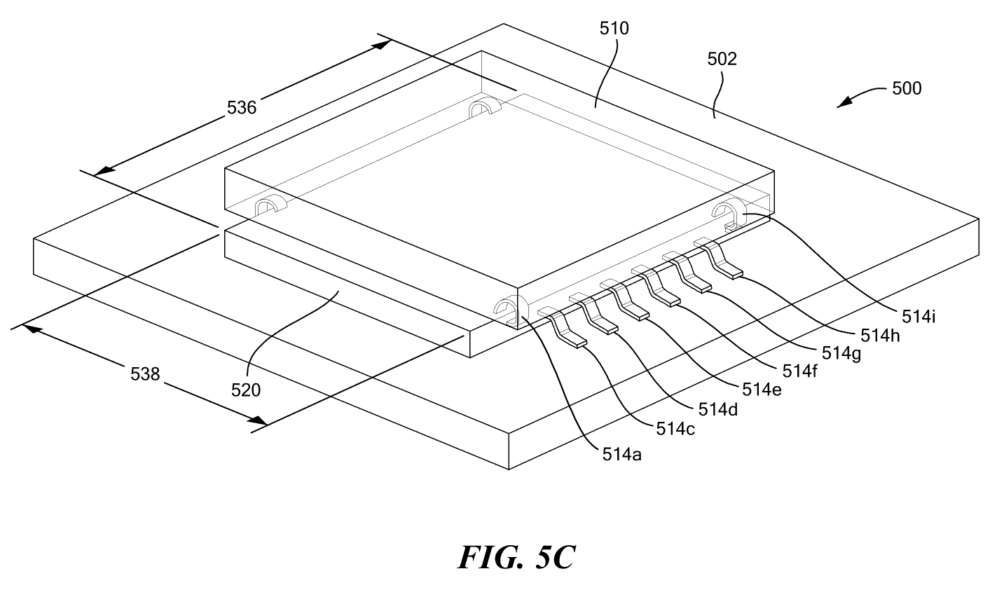

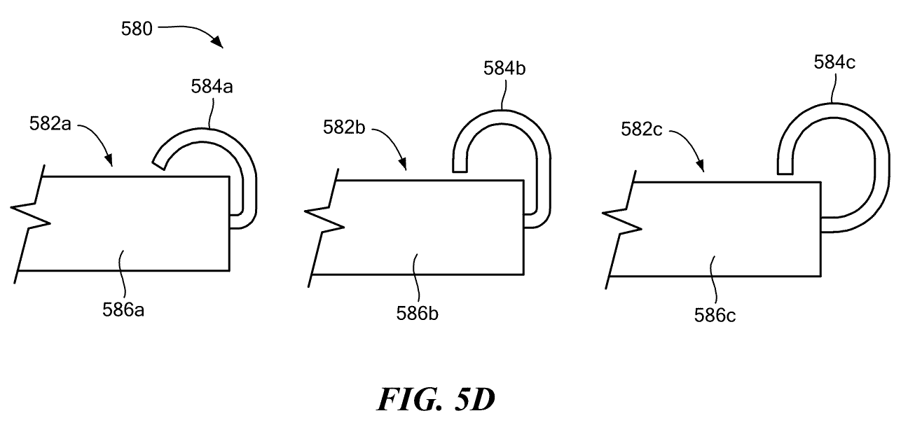

Referring to FIGS. 5A, 5B, and 5C, an IC assembly 500 includes a first component 510 stacked on top of a second component 520, such that the first component 510 and the second component 520 are in a stacked configuration. The IC assembly 500 can be mounted on a substrate 502, which may be similar to or the same as substrate 102. The second component 520 includes a lead set 512a (FIG. 5B), 512c, 512d, 512e, 512f, 512g, 512h (FIG. 5A), 514a (FIG. 5B), 514c, 514d, 514e, 514f, 514g, 514h (FIG. 5A), 514i (FIG. 5C) to permit electrical connection to components within the second component 520. The first component 510 has a first length 534 and a first width 532 to allow for inspection of a subset of the lead set 512c, 512d, 512e, 512f, 512g, 512h, 514c, 514d, 514e, 514f, 514g, 514h (FIG. 5A).

The subset of the lead set 512c, 512d, 512e, 512f, 512g, 512h (FIG. 5A) extends out of the second component 520 at a second length 516 and a subset of the lead set 514c, 514d, 514e, 514f, 514g, 514h (FIG. 5A) extends out of the second component at a length to form the electrical and mechanical connection to the substrate 502. A subset of the lead set 512a, 514a (FIG. 5B), 514i (FIG. 5C) are not visible and thus are not inspectable.

In some embodiments, the second component 520 has a second length 536 and a third width 538. The second length 536 is larger than the first length 534 and the first width 532 is larger than the third width 538. In some embodiments, the first width 532 is a slight or limited amount larger than the third width 538. In some embodiments, the first width 532 is a substantial amount larger than the third width 538.

The second component 520 includes a lead frame 518a, 518b (FIG. 5B), which may be similar to the lead frame 118a, 118b, supports two or more semiconductor dies 513a, 513b, which may be similar to the semiconductor die 113a, 113b. The lead frame 518a, 518b (FIG. 5B) provides the lead set, including leads 512a (FIG. 5B), 512c, 512d, 512e, 512f, 512g, 512h (FIG. 5A), 514a (FIG. 5B), 514c, 514d, 514e, 514f, 514g, 514h (FIG. 5A), 514i (FIG. 5C).

The first component 510 contains a transformer 524, which may be similar to the transformer 124. The first component 510 includes a lead frame 526, which can be similar to lead frame 126, to support the transformer 524 and to provide the lead set 522a, 522b, 522c, 522d (FIG. 5A).

In embodiments, a subset of the lead set, including leads 512a, 514a (FIG. 5B), 514i (FIG. 5C) of the second component 520, are configured for direct electrical connection with leads 522a, 522c, 522d (FIG. 5A) of the first component 510. The two or more leads 512a, 514a (FIG. 5B), 514i (FIG. 5C) from the lead set extend towards the first component 510 to form a direct electrical connection to one or more leads 522a, 522c, 522d (FIG. 5A) of the first component 510. By “direct electrical connection” it is meant that direct physical contact provides an electrical connection between the leads 512a, 514a (FIG. 5B), 514i (FIG. 5C) and the leads 522a, 522c, 522d (FIG. 5A), respectively, as shown. Another subset of the leads from the lead set 512c, 512d, 512e, 512f, 512g, 512h, 514c, 514d, 514e, 514f, 514g, 514h (FIG. 5A) of the second component 520 is configured for direct electrical connection to the substrate 502.

In an embodiment, the IC assembly 500 includes two or more leads 512a, 514a (FIG. 5B), 514i (FIG. 5C) from the first lead set that extend towards a surface 530b of the first component 510. In embodiments, the two or more leads 512a, 514a (FIG. 5B), 514i (FIG. 5C) are bent to form a J-bend. In embodiments, the two or more leads 512a, 514a (FIG. 5B), 514i (FIG. 5C) are curled. In embodiments, the two or more leads 512a, 514a (FIG. 5B), 514i (FIG. 5C) are shaped.

Referring to FIG. 5D, an illustration 580 of various formed leads that may be utilized as the two or more leads 512a, 514a (FIG. 5B), 514i (FIG. 5C) includes the various formed lead configurations 582a, 582b, 582c. The formed lead configurations 582a, 582b, 582c include a formed lead 584a, 584b, 584c, which may be similar to the leads 512a, 514a, 514i that are formed to extend toward the first component 510 of FIGS. 5A-5C, extending to form various j-bends.

A first formed lead configuration 582a includes a first component 586a. A first formed lead 584a extends out from the first component 586a and is formed such that the end of the first formed lead 584a extends out and back towards the first component 586a. The first formed lead 584a forms a j-bend, such as a semicircular shape or a c-shape.

A second formed lead configuration 582b includes a second component 586b. A second formed lead 584b extends out from the second component 586b and is formed such that the end of the second formed lead 584b extends out and back towards the second component 586b. The second formed lead 584b forms a j-bend, such as a j-shape, a curl shape, or an oblong curl shape.

A third formed lead configuration 582c includes a third component 586c. A third formed lead 584c extends out from the third component 586c and is formed such that the end of the third formed lead 584c extends out and back towards the third component 586c. The third formed lead 584c forms a j-bend, such as a circular shape.

It will be appreciated by those of ordinary skill in the art that although the leads 512a (FIG. 5B), 512c, 512d, 512e, 512f, 512g, 512h (FIG. 5A), 514a (FIG. 5B), 514c, 514d, 514e, 514f, 514g, 514h (FIG. 5A), 514i (FIG. 5C), 522a, 522b, 522c, 522d (FIG. 5A) are shown with varying numbers of leads, respectively, other numbers of leads are possible including more or fewer leads. Further, although the leads 512a (FIG. 5B), 512c, 512d, 512e, 512f, 512g, 512h (FIG. 5A), 514a (FIG. 5B), 514c, 514d, 514e, 514f, 514g, 514h (FIG. 5A), 514i (FIG. 5C) extend from the respective component 520 only from opposite parallel component sides, in some embodiments, one or more leads of one or both lead sets can extend from a component side that is orthogonal with respect to the illustrated sides from which they extend.

In embodiments, the first component 510 and the second component 520 are mechanically coupled together. The first component 510 has a top surface 528a and a bottom surface 528b. The second component 520 has a top surface 530a and a bottom surface 530b. In an embodiment, the bottom surface 528b of the first component 510 can contact the top surface 530a of the second component 520.

A non-conductive adhesive 550 may be disposed between first component 510 and the second component 520. The non-conductive adhesive 550 is disposed between the bottom surface 528b of the first component 510 and the top surface 530a of the second component 520 to further enhance mechanical coupling of the components. The non-conductive adhesive 550 may be a polymer or an epoxy. The non-conductive adhesive 550 may be printed, dispensed, or otherwise applied.

Referring to FIG. 5B, the IC configuration 500 is includes an additional feature in the form of electrically conductive material 560, 562, which may be similar to electrically conductive material 160, 162. A first electrically conductive material 560 is disposed on a lead 522a of the first component 510 and a lead 512a of the second component 520. A second electrically conductive material 562 is disposed on lead 522b of the first component 510 and lead 514a of the second component 520. The electrically conductive material 560, 562 can enhance the electrical connection between the leads 522a, 522b (FIG. 5B) of the first component 510 and leads 512a, 514a (FIG. 5B) of the second component 520.

Various embodiments of the concepts, systems, devices, structures and techniques sought to be protected are described herein with reference to the related drawings. Alternative embodiments can be devised without departing from the scope of the concepts, systems, devices, structures and techniques described herein. It is noted that various connections and positional relationships (e.g., over, below, adjacent, etc.) are set forth between elements in the following description and in the drawings. These connections and/or positional relationships, unless specified otherwise, can be direct or indirect, and the described concepts, systems, devices, structures and techniques are not intended to be limiting in this respect. Accordingly, a coupling of entities can refer to either a direct or an indirect coupling, and a positional relationship between entities can be a direct or indirect positional relationship.

As an example of an indirect positional relationship, references in the present description to forming layer "A" over layer "B" include situations in which one or more intermediate layers (e.g., layer "C") is between layer "A" and layer "B" as long as the relevant characteristics and functionalities of layer "A" and layer "B" are not substantially changed by the intermediate layer(s).The following definitions and abbreviations are to be used for the interpretation of the claims and the specification. As used herein, the terms "comprises," "comprising, "includes," "including," "has," "having," "contains" or "containing," or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

The terms "one or more" and "one or more" are understood to include any integer number greater than or equal to one, i.e. one, two, three, four, etc. The terms "a plurality" are understood to include any integer number greater than or equal to two, i.e. two, three, four, five, etc. The term "connection" can include an indirect "connection" and a direct "connection".

References in the specification to "one embodiment, "an embodiment," "an example embodiment," etc., indicate that the embodiment described can include a particular feature, structure, or characteristic, but every embodiment can include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms "upper," "lower," "right," "left," "vertical," "horizontal, "top," "bottom," and derivatives thereof shall relate to the described structures and methods, as oriented in the drawing figures. The terms "overlying," "atop," "on top, "positioned on" or "positioned atop" mean that a first element, such as a first structure, is present on a second element, such as a second structure, where intervening elements such as an interface structure can be present between the first element and the second element. The term "direct contact" means that a first element, such as a first structure, and a second element, such as a second structure, are connected without any intermediary conducting, insulating or semiconductor layers at the interface of the two elements. It should be noted that the term "selective to, "such as, for example, "a first element selective to a second element," means that the first element can be etched and the second element can act as an etch stop.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

The terms “approximately” and “about” may be used to mean within ±20% of a target value in some embodiments, within ±10% of a target value in some embodiments, within ±5% of a target value in some embodiments, and yet within ±2% of a target value in some embodiments. The terms “approximately” and “about” may include the target value. The term “substantially equal” may be used to refer to values that are within ±20% of one another in some embodiments, within ±10% of one another in some embodiments, within ±5% of one another in some embodiments, and yet within ±2% of one another in some embodiments.

The term “substantially” may be used to refer to values that are within ±20% of a comparative measure in some embodiments, within ±10% in some embodiments, within ±5% in some embodiments, and yet within ±2% in some embodiments. For example, a first direction that is “substantially” perpendicular to a second direction may refer to a first direction that is within ±20% of making a 90° angle with the second direction in some embodiments, within ±10% of making a 90° angle with the second direction in some embodiments, within ±5% of making a 90° angle with the second direction in some embodiments, and yet within ±2% of making a 90° angle with the second direction in some embodiments.

It is to be understood that the disclosed subject matter is not limited in its application to the details of construction and to the arrangements of the components set forth in the following description or illustrated in the drawings. The disclosed subject matter is capable of other embodiments and of being practiced and carried out in various ways. Also, it is to be understood that the phraseology and terminology employed herein are for the purpose of description and should not be regarded as limiting. As such, those skilled in the art will appreciate that the conception, upon which this disclosure is based, may readily be utilized as a basis for the designing of other structures, methods, and systems for carrying out the several purposes of the disclosed subject matter. Therefore, the claims should be regarded as including such equivalent constructions insofar as they do not depart from the spirit and scope of the disclosed subject matter.

Although the disclosed subject matter has been described and illustrated in the foregoing exemplary embodiments, it is understood that the present disclosure has been made only by way of example, and that numerous changes in the details of implementation of the disclosed subject matter may be made without departing from the spirit and scope of the disclosed subject matter.

What is claimed is:

1. A voltage isolated integrated circuit (IC) assembly, comprising:
a first component comprising a first width and a first length to form a first recess to allow for inspection of a lead set of a second component, wherein the lead set extends out of the second component at a second length to form an electrical and mechanical connection to a substrate,
wherein the first component is stacked on top of the second component such that the first and second components are in a stacked configuration.

2. The IC assembly of claim 1, wherein the first component has the first recess on one side of the first component and a second recess on an opposing side of the first component such that the first component forms an H shape.

3. The IC assembly of claim 1, wherein the first length, the first width, and a second length of the first component that form the first recess extend to form a C shape.

4. The IC assembly of claim 1, wherein a portion of the first length and the first width of the first component that form the first recess extend at a substantially radiused angle.

5. The IC assembly of claim 1, wherein a portion of the first length and the first width of the first component that form the first recess extend at a substantially right angle.

6. The IC assembly of claim 1, wherein the first component has a third width and a third length to form a third recess.

7. The IC assembly of claim 6, wherein the third width is less than the first width.

8. The IC assembly of claim 6, wherein the third recess is adjacent to the first recess.

9. The IC assembly of claim 6, wherein the third length is smaller than the first length.

10. The IC assembly of claim 1, further comprising two or more leads from the lead set that extend towards the first component to form a direct electrical connection to two or more leads of the first component.

11. A method, comprising:
providing a first component comprising a first length and a first width forming a first recess to allow for inspection of a lead set from a second component, wherein the lead set extends out of the second component at a second length to form an electrical and mechanical connection to a substrate, wherein the first component is stacked on top of the second component such that the first and second components are in a stacked configuration.

12. The method of claim 11, wherein the first component has the first recess on one side of the first component and a second recess on an opposing side of the first component such that the first component forms an H shape.

13. The method of claim 11, wherein the first length, the first width, and a second length of the first component that form the first recess extend to form a C shape.

14. The method of claim 11, wherein the first component has a third width and a third length to form a third recess.

15. The method of claim 14, wherein the third width is less than the first width.

16. The method of claim 14, wherein the third recess is adjacent to the first recess.

17. The method of claim 14, wherein the third length is smaller than the first length.

18. The method of claim 11, further comprising providing two or more leads from the lead set that extend towards the first component to form a direct electrical connection to two or more leads of the first component.

19. A voltage isolated integrated circuit (IC) assembly, comprising:
a second component disposed on a substrate comprising a lead set that extends out of the second component at a second length and connects to the substrate; and
a first component disposed on the second component comprising a first width and a first length to form a first recess to allow for inspection of the lead set, wherein the first component is stacked on top of the second component such that the first and second components are in a stacked configuration.

20. The IC assembly of claim 19, wherein the first component has the first recess on one side of the first component and a second recess on an opposing side of the first component such that the first component forms an H shape.

21. The IC assembly of claim 19, wherein the first length, the first width, and a second length of the first component that form the first recess extend to form a C shape.

22. The IC assembly of claim 19, wherein the first component has a third width and a third length to form a third recess.

23. The IC assembly of claim 22, wherein the third width is greater than the first width.

24. The IC assembly of claim 22, wherein the third recess is adjacent to the first recess.

25. The IC assembly of claim 22, wherein the third length is smaller than the first length.

26. The IC assembly of claim 19, wherein the first component and the second component are mechanically coupled together.

27. The IC assembly of claim 26, further comprising a non-conductive adhesive disposed between the first component and the second component.

28. The IC assembly of claim 19, further comprising two or more leads from the lead set that extend towards the first component to form a direct electrical connection to two or more leads of the first component.

29. A voltage isolated integrated circuit (IC) assembly, comprising:
a second component disposed on a substrate comprising a lead set that extends out of the second component at a second length and connects to the substrate; and
a first component disposed on the second component comprising a first length and a first width to allow for inspection of the lead set.

30. The IC assembly of claim 29, wherein the second component has a second length and a third width, wherein the second length is larger than the first length and the first width is larger than the third width.

31. The IC assembly of claim 29, wherein the first component and the second component are mechanically coupled together.

32. The IC assembly of claim 31, further comprising a non-conductive adhesive disposed between the first component and the second component.

33. The IC assembly of claim 29, further comprising two or more leads from the first lead set that extend towards a bottom surface of the first component.

34. The IC assembly of claim 33, wherein the two or more leads are bent to form a J-bend.

35. The IC assembly of claim 33, wherein the two or more leads are curled.

36. The IC assembly of claim 33, wherein the two or more leads are shaped.

37. The IC assembly of claim 29, further comprising an electrically conductive material positioned on the two or more of the leads.

38. The IC assembly of claim 37, wherein the electrically conductive material is conductive epoxy or solder, non-conductive epoxy, or silicone.
